(19) United States
(12) Patent Application Publication
(10) Pub. No.: US 2006/0231909 A1
(43) Pub. Date: Oct. 19, 2006

(54) METHOD OF MANUFACTURING AN NON-VOLATILE MEMORY DEVICE

(76) Inventors: Hann-Jye Hsu, Taichung County (TW); Ko-Hsing Chang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/309,021

(22) Filed: Jun. 9, 2006

Related U.S. Application Data
(62) Division of application No. 10/707,704, filed on Jan. 6, 2004, now Pat. No. 7,091,550.

(51) Int. Cl. H01L 29/94

(52) U.S. Cl. 257/411

(57) ABSTRACT

A method of manufacturing an non-volatile memory device is provided herein. A substrate is provided and then a trench is formed in the substrate. Thereafter, a bottom oxide layer, a charge-trapping layer and a top oxide layer are sequentially formed over the substrate and the surface of the trench. A conductive layer is formed over the top oxide layer filling the trench. The conductive layer is patterned to form a gate over the trench. The top oxide layer, the charge-trapping layer and the bottom oxide layer outside the gate are removed. A source/drain doping process is carried out. Because the non-volatile memory device is manufactured within the trench, storage efficiency of the device is improved through an increase in the coupling ratio. Furthermore, more charges can be stored by increasing the depth of the trench.

### CROSS-REFERENCE TO RELATED APPLICATION

This is a divisional application of application Ser. No. 10/707,704, filed on Jan. 6, 2004 and is now allowed. The entirety of the above-mentioned patent application is hereby incorporated by reference herein and made a part of this specification.

### BACKGROUND OF THE INVENTION

1, Field of the Invention

The present invention relates to a manufacturing method of a memory device and thereof. More particularly, the present invention relates to a method of manufacturing an non-volatile memory device.

2. Description of the Related Art

Electrically erasable programmable read-only memory (EEPROM) is a non-volatile memory device that allows multiple data writing, reading, and erasing operations. In addition, the stored data will be retained even after power to the device is removed. With these advantages, it has been broadly applied in personal computer and electronic equipment. A typical EEPROM device has a floating gate and a control gate fabricated using doped polysilicon. During a programming operation, electrons injected into the floating gate will be evenly distributed over the entire polysilicon floating gate layer. Obviously, if the tunneling oxide layer underneath the polysilicon floating gate contains some defects, a leakage current will be produced and reliability of the device will be affected.

To resolve the leakage problem in an EEPROM device, the polysilicon floating gate of a conventional memory device is replaced by a charge-trapping layer. The charge-trapping layer is a silicon nitride layer with silicon oxide layers above and below the silicon nitride layer, thereby creating an oxide/nitride/oxide (ONO) composite stacked structure. An EEPROM having this stacked gate structure is often referred to as a silicon/oxide/nitride/oxide/silicon (SONOS) memory device.

FIG. 1 is a cross-sectional view of a conventional SONOS memory device. As shown in FIG. 1, an oxide/nitride/oxide (ONO) composite layer 102 is formed over a substrate 100. The ONO composite layer 102 includes a bottom oxide layer 104, a silicon nitride layer 106 and a top oxide layer 108. In addition, a polysilicon gate 112 is formed over the ONO composite layer 102 to serve as a word line. A source/drain region 118 is formed in the substrate 100 on each side of the ONO composite layer 102 to serve as a buried bit line. Spacers 116 are also formed on the sidewalls of the polysilicon gate 112. A lightly doped region 114 is formed in the substrate 100 underneath the spacers 116 to connect with the source/drain region 118 electrically.

In general, the SONOS memory device is programmed by injecting channel hot electrons (CHE) through the bottom oxide layer 104 and trapping the electrons within the ONO composite layer 102. Furthermore, data within the SONOS memory device is erased by injecting tunneling enhanced hot holes (TEHH) through the bottom oxide layer 104 and annulling the trapped electrons inside the ONO composite layer 102. The storage capacity of a SONOS memory device mainly depends on the coupling ratio. In other words, the contact area between the aforementioned top oxide layer 108 and the polysilicon gate 112.

Through the widespread miniaturization of semiconductor devices, line width of each device is shrunk correspondingly. When the contact area between the top oxide layer and the polysilicon gate inside the SONOS memory device is reduced, overall storage capacity is affected. Consequently, scientists and engineers are now working hard to find methods for increasing the coupling ratio and hence boosting the storage capacity of a SONOS memory device.

### SUMMARY OF THE INVENTION

Accordingly, at least one objective of the present invention is to provide a non-volatile memory device with a higher coupling ratio despite device miniaturization and a method of manufacturing the same.

At least a second objective of this invention is to provide a non-volatile memory device with a smaller dimension but a higher coupling ratio so that overall storage efficiency of the device is improved.

To achieve these and other advantages and in accordance with the purpose of the invention, as embodied and broadly described herein, the invention provides a method of fabricating a non-volatile memory device. A substrate is provided and then a trench is formed in the substrate. Thereafter, a bottom oxide layer, a charge-trapping layer and a top oxide layer are sequentially formed over the substrate and the surface of the trench. A conductive layer is formed over the top oxide layer filling the trench. The conductive layer is patterned to form a gate over the trench. The top oxide layer, the charge-trapping layer and the bottom oxide layer outside the gate are removed. Finally, a source/drain doping process is carried out.

This invention also provides a non-volatile memory device. The non-volatile memory device includes a substrate, a gate, a bottom oxide layer, a charge-trapping layer, a top oxide layer and a plurality of source/drain regions. The substrate has a trench. The gate is located over and completely filling the trench. The bottom oxide layer is located between the gate and the trench surface. The charge-trapping layer is located between the gate and the bottom oxide layer and the top oxide layer is located between the gate and the charge-trapping layer. The source/drain regions are located within the substrate outside the gate.

Because the non-volatile memory device is fabricated within a trench in this invention, the coupling ratio of the device can be increased under the same device dimension so that the storage efficiency of the memory device is improved. Furthermore, depth of the trench is adjustable so that more charges can be stored inside the non-volatile memory device. In other words, the threshold voltage (Vₜ) for programming data can be changed by adjusting the depth of the trench. In addition, the process for fabricating the non-volatile memory is a single polysilicon process and hence is also applicable in an embedded process.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a conventional SONOS memory device.

FIGS. 2A through 2D are schematic cross-sectional views showing the progression of steps for fabricating a non-volatile memory device according to one preferred embodiment of this invention.

FIG. 3 is a cross-sectional view of a trench in a non-volatile memory device according to another embodiment of this invention.

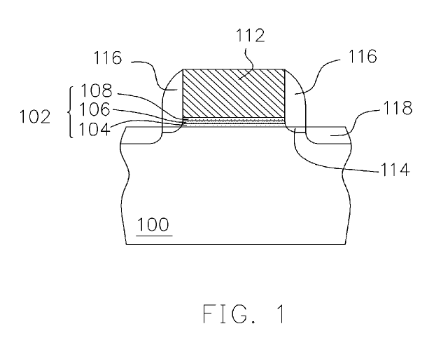

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

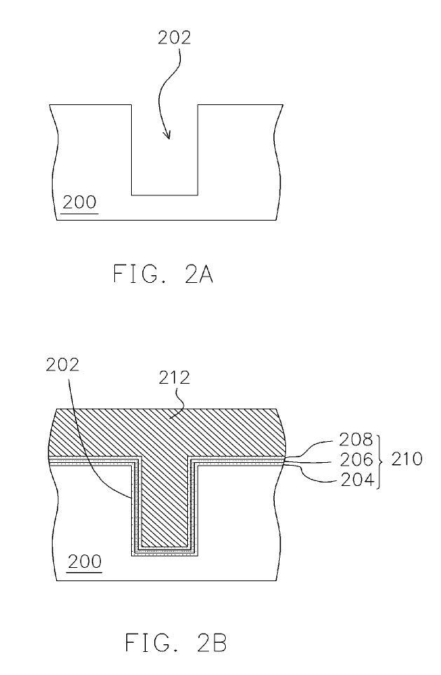

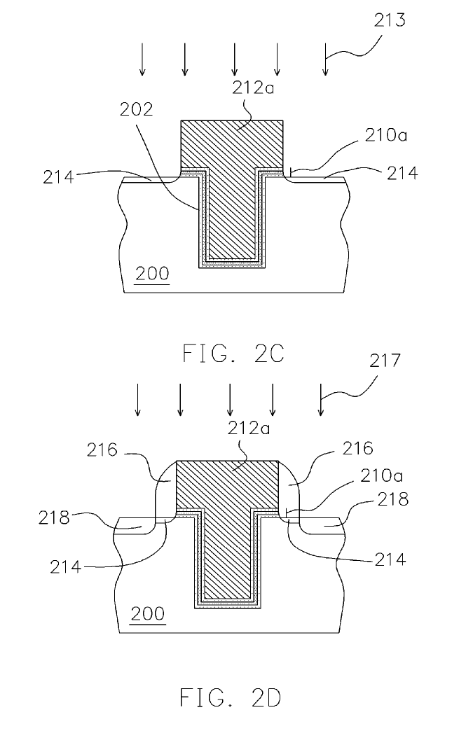

FIGS. 2A through 2D are schematic cross-sectional views showing the progression of steps for fabricating a non-volatile memory device according to one preferred embodiment of this invention. As shown in FIG. 2A, a substrate 200 is provided. Thereafter, a trench 202 is formed in the substrate 200. To form the trench 202, a pad oxide layer (not shown) is first formed over the substrate 200. A patterned mask layer (not shown) fabricated from silicon nitride or other suitable material is next formed over the pad oxide layer. Using the patterned mask layer as a mask, the exposed pad oxide layer and a portion of the substrate 200 is removed. Finally, the pad oxide layer and the patterned mask layer are removed.

As shown in FIG. 2B, a bottom oxide layer 204 is formed over the substrate 200 and the surface of the trench 202. The bottom oxide layer 204 is a silicon oxide layer formed, for example, by performing a thermal oxidation process. Thereafter, a charge-trapping layer 206 is formed over the bottom oxide layer 204. The charge-trapping layer 206 can be a silicon nitride layer formed, for example, by performing a chemical vapor deposition (CVD) process. Furthermore, the charge-trapping layer 206 can be a nitridation layer, a tantalum oxide layer, a titanic strontium layer or a hafnium oxide layer, for example. A top oxide layer 208 is formed over the charge-trapping layer 206. The top oxide layer 208 can be a silicon oxide layer, for example. A conductive layer 212 that fills the trench 202 is formed over the top oxide layer 208. The conductive layer 212 is fabricated using polysilicon or some other suitable material, for example. The bottom oxide layer 204, the charge-trapping layer 208, the top oxide layer 208, the conductive layer 212 together form the stacked structure of a silicon/oxide/nitride/oxide/silicon (SONOS) memory device.

As shown in FIG. 2C, the conductive layer 212 is patterned to form a gate 212a over the trench 202. The gate 212a may extend over a portion of the substrate 200 (as shown in the figure) outside the trench 202 or may form directly over the trench 202. Thereafter, the bottom oxide layer 204, the charge-trapping layer 206 and the top oxide layer 208 outside the gate 212a are removed to form an oxide/nitride/oxide (ONO) composite layer 210a. Afterwards, a light doping process 213 may be selectively carried out to form a lightly doped region 214 in the substrate 200 outside the gate 212a.

As shown in FIG. 2D, spacers 216 are selectively formed on the sidewalls of the gate 212a. The spacers 216 are fabricated using, for example, silicon nitride or some other suitable material. Thereafter, a source/drain doping process 217 is carried out to form source/drain regions 218 in the substrate 200 outside the gate spacers 216. After the source/drain doping process 217, a self-aligned suicide (Salicide) process may be carried out to form a metal silicide layer (not shown) on the surface of the gate 212a. The silicide layer can be a cobalt silicide layer, a titanium silicide layer, a tungsten silicide layer, a molybdenum silicide layer, a platinum silicide layer or a nickel silicide layer, for example. Furthermore, before performing the salicide process, a salicide block (SAB) layer is often formed over a portion of the substrate 200 to cover areas where a silicide layer is not required.

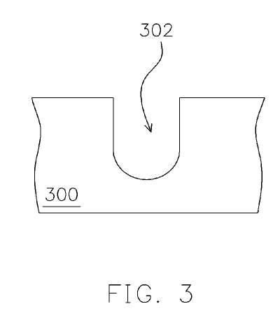

In addition, the trench 202 can have a smooth profile aside from the one shown in FIGS. 2A through 2D. FIG. 3 is a cross-sectional view of a trench in a non-volatile memory device according to another embodiment of this invention. As shown in FIG. 3, a smooth trench 302 instead of the square bottom trench 202 as shown in FIGS. 2A through 2D is formed in a substrate 300.

In summary, one major aspect of this invention is the fabrication of a non-volatile memory device inside a trench so that the coupling ratio of the device can be increased under the same device dimension. Ultimately, the storage efficiency of the memory device is improved. Furthermore, depth of the trench is adjustable so that more charges can be stored inside the non-volatile memory device. In other words, the threshold voltage (Vₜ) for programming data can be changed by adjusting the depth of the trench. In addition, the process for fabricating the non-volatile memory is a single polysilicon process and hence is also applicable in an embedded process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating an non-volatile memory device, comprising of:
providing a substrate;
forming a trench in the substrate;
forming a bottom oxide layer on the substrate and the surface of the trench;
forming a charge-trapping layer over the bottom oxide layer;
forming a top oxide layer over the charge-trapping layer;
forming a conductive layer over the top oxide layer and filling the trench;
patterning the conductive layer to form a gate over the trench;
removing the top oxide layer, the charge-trapping layer and the bottom oxide layer outside the gate; and
forming source/drain regions besides the gate by performing a doping process.

2. The method of claim 1, wherein before forming the trench in the substrate, the method further comprises a step of isolating active regions on the substrate.

3. The method of claim 1, wherein the step of forming the bottom oxide layer on the substrate and the surface of the trench comprises performing a thermal oxidation process to form the bottom oxide layer.

4. The method of claim 1, wherein the step of forming the charge-trapping layer over the bottom oxide layer comprises performing a chemical vapor deposition process to form a silicon nitride layer as the charge-trapping layer.

5. The method of claim 1, wherein before forming the source/drain regions, the method further comprises:
performing a light doping process; and
forming spacers on the sidewalls of the gate.

6. The method of claim 1, wherein the gate extends to the substrate surface outside the trench.

7. The method of claim 1, wherein the method comprises a step of performing a self-aligned silicide process to form a silicide layer over the gate surface.

8. The method of claim 7, wherein before performing the self-aligned silicide process, the method further comprises forming a self-aligned metal silicide blocking layer over a portion of the substrate.
